(19) United States
(12) Patent Application Publication
(10) Pub. No.: US 2002/0072172 A1
(43) Pub. Date: Jun. 13, 2002

(54) Method of fabricating a storage node

(76) Inventors: Chi-Horn Pai, Taipei City (TW); Chih-Yuan Hsiao, Fang-San City (TW)

Correspondence Address: NAIPO (NORTH AMERICA INTERNATIONAL PATENT OFFICE), P.O. BOX 506, MERRIFIELD, VA, 22116, US

(21) Appl. No.: 09/731,840

(22) Filed: Dec. 8, 2000

(51) Int. Cl. H01L 21/8242; H01L 21/20

(52) U.S. Cl. 438/254; 438/253; 438/255; 438/396; 438/397; 438/398

(57) ABSTRACT

A method of fabricating a storage node is achieved. The method includes: (1) providing a substrate, positioned with at least a first conductive layer, (2) forming a dielectric layer on and completely covering the substrate, (3) forming a contact hole within the dielectric layer to connect with the conductive layer, (4) forming a second conductive layer on the dielectric layer and filling in the contact hole, (5) forming a silicide layer and a third conductive layer, respectively, on the second conductive layer, (6) forming a patterned photoresist layer on the third conductive layer, to define the pattern and position of the storage node, (7) etching the third conductive layer, the silicide layer and the second conductive layer uncovered by the photoresist layer down to the surface of the dielectric layer, (8) removing the photoresist layer, and (9) wet etching the silicide layer to finish the fabrication of the fin-type storage node.

### BACKGROUND OF THE INVENTION

1. Field of the Invention

The present invention relates to a method of fabricating a storage node on the surface of a semiconductor wafer, and more particularly, to a method of increasing the surface area of the storage node.

2. Description of the Prior Art

Dynamic random access memory (DRAM) is composed of numerous memory cells. A memory cell is composed of a metal-oxide semiconductor field-effect transistor (MOSFET), functioning as a pass transistor, and a capacitor for storing charges. The electrical charge is read and written through an access composed of the storage node of the capacitor, the conductive plug which fills the contact hole, and the drain of the MOSFET. One of the electrical layers obtains induced charges while another supplies a voltage, enabling the capacitor to memorize or output data.

The capacitor is important in data storage of a memory cell. The more charges a capacitor of the DRAM cell can store, the less affected is a sense amplifier in retrieving data to minimize mistakes such as soft errors. Also, the frequency of recharge is reduced. There are two current approaches to increase the storage capacity of a capacitor. The first method uses a dielectric material of a higher dielectric constant to deposit between a storage node and field plate of a capacitor. In the second method, the surface area of a capacitor, particularly the surface area of the storage node and the field plate, is enlarged to increase the total number of charges stored in the capacitor. Presently, most capacitor dielectric layers are made of an ONO (oxide/nitride/oxide) composite structure. This structure not only reduces the thickness of a single capacitor cell (to approximately 5 nm) but also provides a better dielectric constant with a higher number of charges stored in the capacitor per unit area. The present invention provides a method of increasing the surface area of the capacitor.

Please refer to FIG. 1 to FIG. 3. FIG. 1 to FIG. 3 are schematic diagrams of a method of manufacturing a stacked capacitor cell (STC) of a DRAM according to the prior art. All elements needed by the STC are first prepared. As illustrated in FIG. 1, a symmetrical pair of field oxide layers 14 is formed on the silicon substrate 12 of the surface of a semiconductor wafer 10 using a local oxidation of silicon (LOCOS) method. Then, a dielectric layer 16, comprising a symmetrical pair of doped polysilicon bit lines 18, is deposited over the pair of field oxide layers 14. A neutral silicate glass (NSG) layer 20 is then deposited over the dielectric layer 16 for protection and isolation. Finally, a photoresist layer 22 is coated over the NSG layer 20, followed by etching to form a hole 23 penetrating the center of the photoresist layer 22 to the surface of the NSG layer 20 to define the position of a contact hole 24.

Secondly, as illustrated in FIG. 2, a contact hole 24 is etched from the surface of the NSG layer 20 beneath the hole 23 down to the surface of the silicon substrate 12 by an anisotropic etching method followed by the removal of the photoresist layer 22. Next, a SiO₂ spacer 26 of approximately 1000 Å thick is uniformly deposited over the surface of the side wall of the contact hole 24 using chemical vapor deposition (CVD) and etch back methods. Use of the etch back technique, reduces the thickness of the NSG layer 20 from 2300 Å to approximately 1000 Å.

Next, as illustrated in FIG. 3, a polysilicon layer (not shown) is again deposited over the contact hole 24 using the CVD method with ionic phosphorus simultaneously doped in-situ. This method creates a doped polysilicon layer of uniform thickness over both the contact hole 24 and NSG layer 20. Then, using photolithography and etch methods, the undesired portion of the doped polysilicon layer is removed to form a mushroom-shaped storage node 28. Alternatively, along with the creation of the doped polysilicon layer, ionic dopants like phosphorus may be introduced into the polysilicon layer by ion implantation.

Finally, an ONO composite dielectric layer 30 and a field plate 32 are formed, respectively, on the surface of the storage node 28. A nitride layer approximately 5 nm thick is directly deposited on the surface of the storage node 28 by the CVD method, then a passing vapor of 920° C. is used to reoxide the surface of the nitride layer to form an oxide layer approximately 2 nm thick. The addition of the native oxide layer on the polysilicon surface of the storage node 28 forms the ONO composite dielectric layer 30 of the single cell. CVD is again used to deposit a polysilicon layer to form the field plate 32 and completes the production of a typical stacked capacitor cell (STC).

### SUMMARY OF THE INVENTION

It is an objective of the present invention to provide a method of fabricating the storage node of capacitors.

It is another objective of the present invention to provide a method of fabricating a fin-type storage node to effectively enlarge the surface area of the storage node to allow the ONO dielectric layer and the field plate to obtain larger surfaces for charge storage.

In a preferred embodiment, the present invention of fabricating the storage node includes the following steps: (1) providing a substrate, positioned with at least a first conductive layer, (2) forming a dielectric layer on and completely covering the substrate, (3) performing a photolithography and etching processes to form a contact hole within the dielectric layer to connect with the conductive layer, (4) forming a second conductive layer on the dielectric layer and filling in the contact hole, (5) forming a silicide layer and a third conductive layer, respectively, on the second conductive layer, (6) forming a patterned photoresist layer on the third conductive layer to define the pattern and position of the storage node, (7) etching the third conductive layer, the silicide layer and the second conductive layer uncovered by the photoresist layer down to the surface of the dielectric layer, (8) removing the photoresist layer, and (9) wet etching the silicide layer to finish fabrication of the fin-type storage node.

It is an advantage of the present invention that a RCA standard clean solution is used to selectively etch both the doped polysilicon layer and the silicide layer to produce the fin-type storage node. In addition, a standard HSG process is performed on the surface of the storage node to increase its surface area and consequently, to increase the capacitance of a STC. As a result, the recharging frequency of the STC is greatly reduced.

These and other objectives of the present invention will no doubt become obvious to those of ordinary skill in the art after reading the following detailed description of the preferred embodiment, which is illustrated in the various figures and drawings.

### BRIEF DESCRIPTION OF THE DRAWINGS

FIG. 1 to FIG. 3 are schematic diagrams of a prior art method of fabricating a DRAM stacked capacitor cell.

FIG. 4 to FIG. 7 are schematic diagrams of fabricating a fin-type stacked capacitor cell according to the present invention.

FIG. 8 is a schematic diagram of a second embodiment according to the present invention.

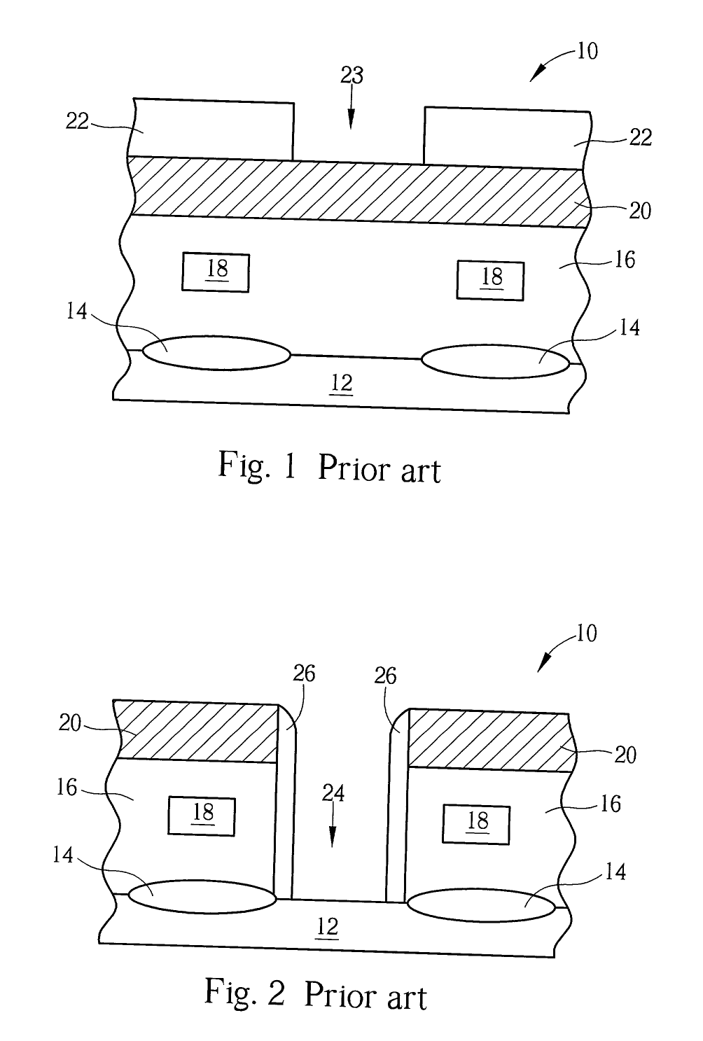

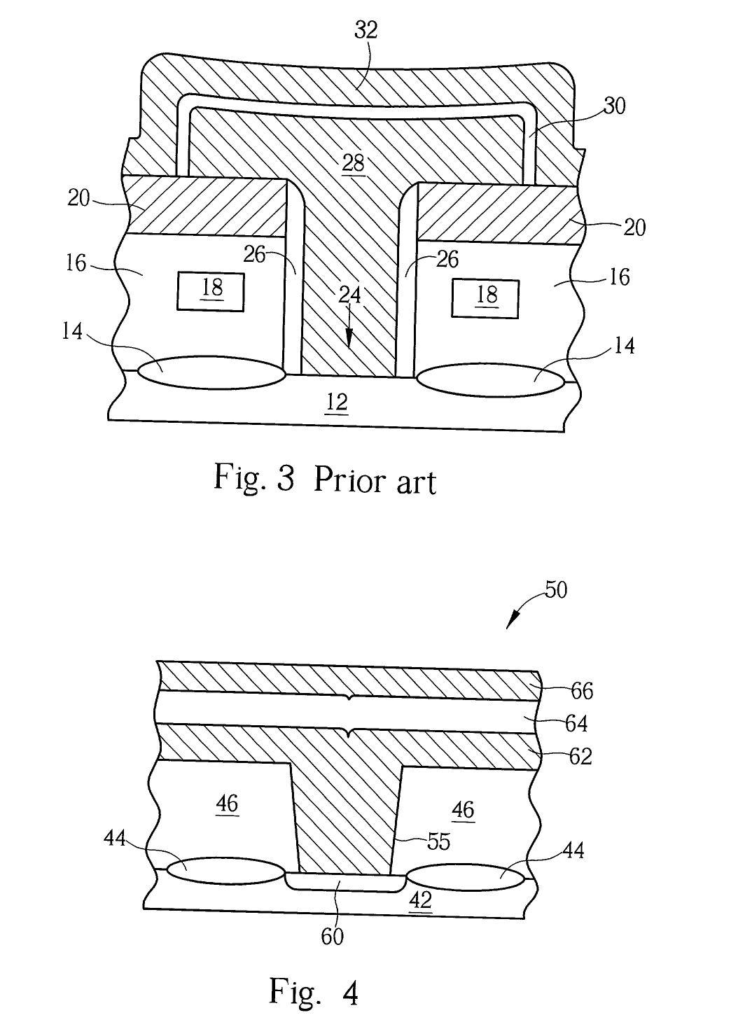

### DETAILED DESCRIPTION OF THE PREFERRED EMBODIMENT

Please refer to FIG. 4 to FIG. 7. FIG. 4 to FIG. 7 are schematic diagrams of fabricating a fin-type stacked storage node according to the present invention. Firstly, as illustrated in FIG. 4, a symmetrical pair of field oxide layers 44 and a doped area 60, insulated by the pair of field oxide layers 44, are formed, respectively, on a silicon substrate 42 of the surface of a semiconductor wafer 50. The doped area 60 functions as a drain or source of a MOS transistor. In another embodiment, a silicon-on-insulator (SOI) substrate is used to replace the silicon substrate 42.

Then, a dielectric layer 46 of several thousand angstroms thick is deposited on the silicon substrate 42 and completely covers the doped area 60. The dielectric layer 46 is composed of silicon dioxide (SiO₂), phosphosilicate glass (PSG) or other similar materials of a low dielectric constant. After deposition of the dielectric layer 46, a chemical mechanical polishing (CMP) process is selectively performed to obtain a smooth surface. Then, a photolithography and etch methods are used to form a contact hole 55 penetrating through the dielectric layer 46 to the surface of the doped area 60.

A low-pressure chemical vapor deposition (LPCVD) is performed to deposit a uniform polysilicon layer 62 of approximately 1000 Å thick on the dielectric layer 46. Conditions of the LPCVD process include: silane (SiH4) as a reactive gas, a process temperature of 575˜650° C., and a process pressure of 0.3˜0.6 Torr.

The polysilicon layer 62 deposited by LPCVD has a high enough resistance that a doping process is required to reduce the resistance of the polysilicon layer 62. The doping method involves introducing a reactive gas together with the dopants, such as the simultaneous introduction of phosphine (PH₃) gas into the CVD reactor, to enable deposition of the polysilicon layer 62, with in-situ doping. The most important step is then the filling in of the contact hole 55 with the polysilicon layer 62.

Next, a silicide CVD is performed to deposit a 1500 to 2000 Å thick silicide layer 64 on the surface of the polysilicon layer 62. The silicide layer 64 is composed of tungsten silicide (WSiₓ), titanium silicide (TiSiₓ), tantalum silicide (TaSiₓ) or molybdenum silicide (MoSiₓ). In contrast to the other compounds, the tungsten silicide has the following advantages: (1) better bonding with the polysilicon surface, (2) less peeling problems and (3) a lower reaction temperature of formation. Due to the above advantages, tungsten silicide is used in the better embodiment of the present invention. A typical tungsten silicide CVD process uses both tungsten hexafluoride (WF₆) and silane (SiH₄) as reactive gases, a process temperature between 300 and 400° C. and a process pressure between 0.3 and 0.1 Torr. The same LPCVD process used to deposit the polysilicon layer 62 is performed again to deposit a doped polysilicon layer 66 of approximately 1000 Å thick on the surface of the tungsten silicide layer 64.

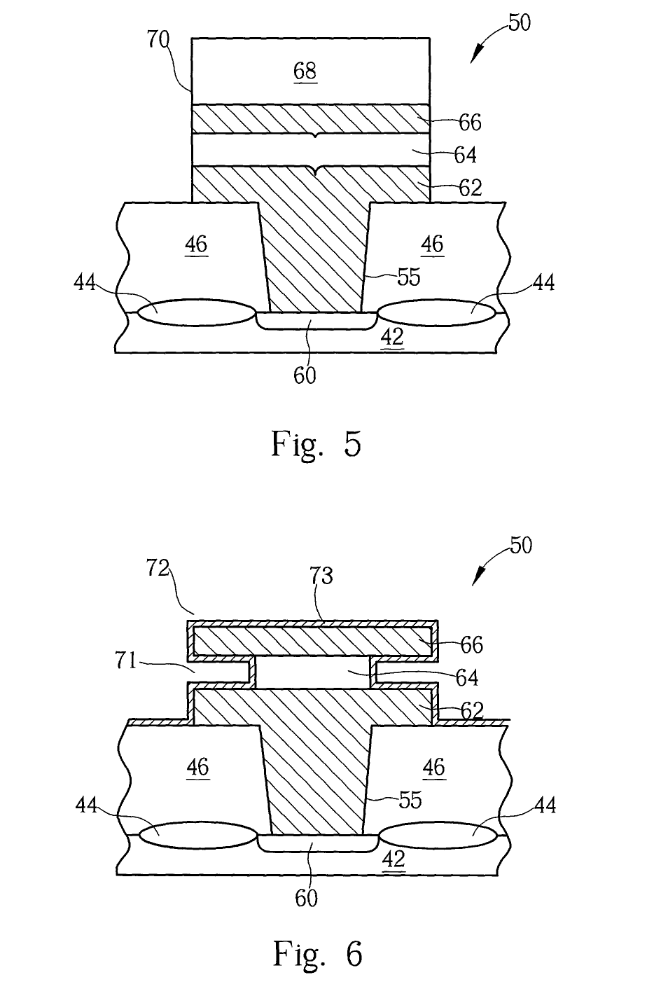

As illustrated in FIG. 5, an exposed and developed photoresist layer 68 is formed on the surface of the doped polysilicon layer 66 to define the pattern and position of the storage node. A dry etching process is then used, utilizing the photoresist layer 68 as a mask, to etch down through the doped polysilicon layer 66, the silicide layer 64 and the polysilicon layer 62 to the surface of the dielectric layer 46. After the photoresist layer 68 is removed, a stacked structure 70 is finally formed. To reduce the resistance of the silicide layer 64, a rapid thermal annealing (RTA) process is selectively performed to lower the resistance below 70 μΩ-cm. To avoid affecting the junction depth of the doped area 60, both the heating rate and temperature must be strictly controlled.

Next, as illustrated in FIG. 6, a wet etching process is performed on the silicide layer 64 to form a recess 71 in the stacked structure 70 and produce a fin-type stacked structure 72. The RCA standard clean solution or other similar clean solutions may be used in the wet etching process of the silicide layer 64 to selectively etch the silicide layer 64. More specifically, the semiconductor wafer 50 is immersed in a composite solution (normally called SC-2 solution) with a volume ratio composition of HCl:H₂O₂:H₂O=1:1:6. The immersion takes place from several seconds to minutes under a temperature between 25 to 70° C. to finally produce the fin-type stacked structure 72. Next, a LPCVD is again performed to deposit an amorphous silicon layer 73 with a uniform thickness of approximately 500 Å on the surface of the fin-type stacked structure 72. Conditions of the LPCVD process include: silane (SiH4) as a reactive gas, a process temperature of 575˜650° C., and a process pressure of 0.3˜0.6 Torr.

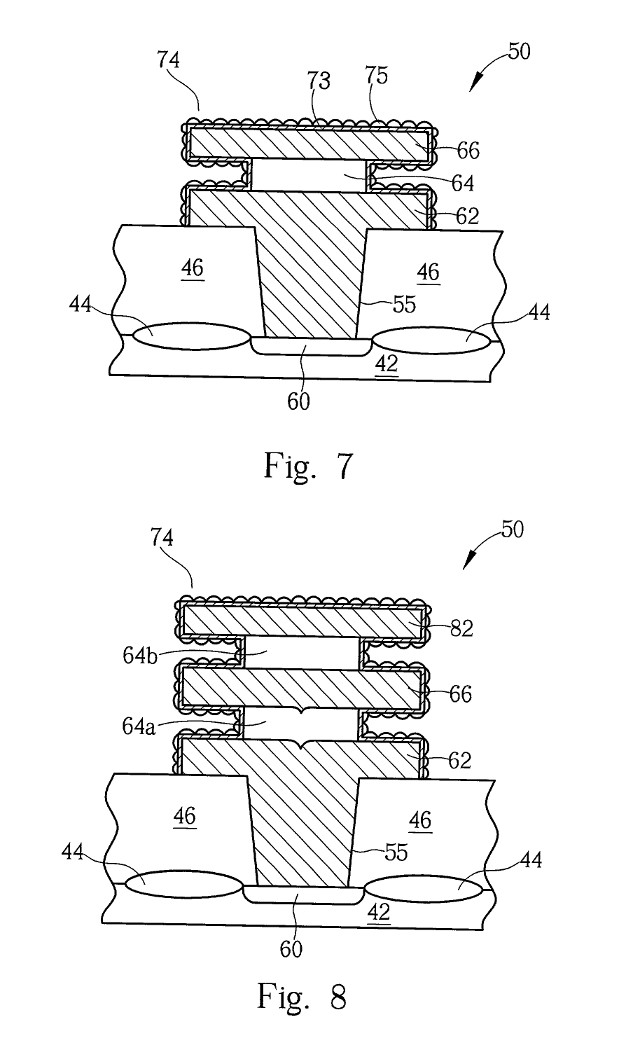

As illustrated in FIG. 7, the amorphous silicon layer 73 present on the surface of the dielectric layer 46 is removed. The method of removing the amorphous silicon layer 73 involves performing a dry etching process. Then, a dry etching process is performed on the amorphous silicon layer 73 uncovered by the photoresist mask. Next, an ultra high vacuum chemical vapor deposition (UHVCVD) is performed, using both silane and dichlorosilane (SiH₂Cl₂) as reactive gases, a process pressure below 1 Torr and a temperature between 550 and 800° C., to deposit a uniform polysilicon layer 75 with a hemi-spherical grain (HSG) structure on the surface of the amorphous silicon layer 73. So far, production of the fin-type stacked storage node 74 is finished. The polysilicon layer 75 is approximately 500 Å in thickness. A subsequent annealing process in a nitrogen atmosphere is used to drive the phosphoric atoms in the storage node 74 into the HSG polysilicon layer 75. The above process also transforms the storage node 74 from an amorphous silicon material to that of polysilicon.

Please refer to FIG. 8. FIG. 8 is a schematic diagram of a second embodiment according to the present invention. As illustrated in FIG. 8, the fin-type stacked storage node 74 may also be composed of three doped polysilicon layers 62, 66, 82, and two silicide layers 64a, 64b. Alternatively, any positional variation of the plurality of the silicide layers and the doped polysilicon layers of the stacked composition can produce the fin-type storage node according to the present invention.

In contrast to the prior art of fabricating the storage node, the present invention utilizes the RCA standard clean solution to selectively etch both the doped polysilicon layer and the silicide layer to produce the fin-type storage node. In addition, a standard HSG process is performed on the surface of the storage node, to increase its surface area and hence increase the capacitance of a STC. As a result, the recharging frequency of the STC is greatly reduced.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method of fabricating a storage node comprising:
providing a substrate positioned with at least a first conductive layer;
forming a dielectric layer on the substrate to completely cover the conductive layer;
performing a photolithographic and etching processes to form a contact hole within the dielectric layer to connect with the conductive layer;
forming a second conductive layer on the surface of the dielectric layer and filling in the contact hole;
forming a silicide layer and a third conductive layer on the second conductive layer, respectively;
forming a photoresist layer positioned above the contact hole on the third conductive layer to define the pattern of the storage node;
etching the third conductive, the silicide and the second conductive layers uncovered by the photoresist layer down to the surface of the dielectric layer;
removing the photoresist layer; and
wet etching the silicide layer to form a fin-type storage node.

2. The method of claim 1 wherein the first conductive layer functions as a drain or source of a MOS transistor.

3. The method of claim 1 wherein the silicide layer is composed of tungsten silicide (WSiₓ) or titanium silicide (TiSiₓ).

4. The method of claim 1 wherein the silicide layer is approximately 1500 to 2000 angstroms (Å) in thickness.

5. The method of claim 1 wherein the second conductive layer is composed of doped polysilicon.

6. The method of claim 1 wherein the third conductive layer is composed of doped polysilicon.

7. The method of claim 1 wherein both the second and the third conductive layers are 1000 angstroms in thickness.

8. The method of claim 1 wherein a RCA standard clean solution is used during the wet etching process of the silicide layer.

9. The method of claim 1 wherein the substrate is a silicon or a silicon-on-insulator (SOI) substrate.

10. The method of claim 1 wherein the dielectric layer undergoes chemical mechanical polish (CMP).

11. The method of claim 1 comprises further steps after the wet etching process of the silicide layer as following:
forming an amorphous silicon layer on the surface of the fin-type storage node; and
performing a hemi-spherical grain (HSG) process to form a uniform, HSG structure of polysilicon on the surface of the amorphous silicon layer.

12. A method of fabricating a stacked storage node on a substrate, the substrate comprising at least a MOS transistor, the method comprising:
forming a dielectric layer on the substrate to completely cover the MOS transistor;
performing a photolithographic and etching processes to form a contact hole within the dielectric layer to connect with a drain or source of the MOS transistor;
forming a conductive stack composed of a plurality of silicide layers and a plurality of doped silicon layers on the surface of the dielectric layer and filling in the contact hole;
forming a photoresist layer positioned above the contact hole on the third conductive layer to define the pattern of the storage node;
etching the conductive stack uncovered by the photoresist layer down to the surface of the dielectric layer;
removing the photoresist layer; and
wet etching the plurality of silicide layers to form a fin-type stacked storage node.

13. The method of claim 12 wherein all silicide layers in the conductive stack are composed of tungsten silicide (Wsiₓ) or titanium silicide (TiSiₓ).

14. The method of claim 13 wherein all silicide layers in the conductive stack are approximately 1500 to 2000 angstroms in thickness.

15. The method of claim 12 wherein all doped silicon layers in the conductive stack are 1000 angstroms in thickness.

16. The method of claim 12 wherein the substrate is a silicon or a silicon-on-insulator substrate.

17. The method of claim 12 wherein a RCA standard clean solution is used during the wet etching process of the plurality of silicide layers.

18. The method of claim 12 wherein the dielectric layer undergoes chemical mechanical polish.

19. The method of claim 12 comprises further steps following the wet etching process of the plurality of silicide layers wherein:
forming an amorphous silicon layer on the surface of the fin-type storage node; and
performing a hemi-spherical grain (HSG) process to form a uniform, HSG structure of polysilicon on the surface of the amorphous silicon layer.
